(19) United States
(12) Patent Application Publication
(10) Pub. No.: US 2023/0411323 A1
(43) Pub. Date: Dec. 21, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Etsuko WATANABE, Tokyo (JP); Takashi TONEGAWA, Tokyo (JP)

(21) Appl. No.: 18/188,781

(22) Filed: Mar. 23, 2023

(30) Foreign Application Priority Data
May 23, 2022 (JP) 2022-083806

(51) Int. Cl. H01L 23/00

(52) U.S. Cl. CPC H01L 24/06; H01L 23/49513; H01L 24/40; H01L 24/48; H01L 24/05; H01L 24/73; H01L 24/03; H01L 2924/13055; H01L 2924/13091; H01L 2224/05553; H01L 2224/05554; H01L 2224/0603; H01L 2224/06051; H01L 2224/06181; H01L 2224/06505; H01L 2224/06102; H01L 2224/05018; H01L 2224/05027; H01L 2224/05166; H01L 2224/05184; H01L 2924/0132; H01L 2224/05186; H01L 2924/04941; H01L 2224/05124; H01L 2224/05138; H01L 2924/01014; H01L 2224/05147; H01L 2924/0133; H01L 2224/05155; H01L 2224/05083; H01L 2224/05084; H01L 2224/05644; H01L 2224/05624; H01L 2224/05638; H01L 2224/05647; H01L 2224/05664; H01L 2224/05118; H01L 2224/05567; H01L 2224/03464; H01L 2224/48245; H01L 2224/48091; H01L 2224/37147; H01L 2224/37139; H01L 2224/40245; H01L 24/29; H01L 2224/29139; H01L 24/32; H01L 2224/32245; H01L 2224/73221; H01L 2224/73265; H01L 2224/73263; H01L 24/37

(57) ABSTRACT

A dielectric layer has a first opening exposing a surface of a first conductive layer and a second opening exposing a surface of a second conductive layer and having an opening area smaller than an opening area of the first opening. A material of the surface of the second conductive layer exposed from the second opening is different from a material of the surface of the first conductive layer exposed from the first opening, and includes aluminum.

### CROSS-REFERENCE TO RELATED APPLICATIONS

The disclosure of Japanese Patent Application No. 2022-083806 filed on May 23, 2022, including the specification, drawings and abstract is incorporated herein by reference in its entirety.

### BACKGROUND

The present invention relates to a semiconductor device and method of manufacturing the same, for example, the present invention can be suitably applied to a semiconductor device and a method of manufacturing the same, which has electrode pads for detecting potentials of sources or emitters.

There are disclosed techniques listed below.

### [Patent Document 1] Japanese Unexamined Patent Application Publication No. 2010-123686

Patent Document 1 discloses a power MOSFET (Metal Oxide Semiconductor Field Effect Transistor) having a source pad electrode having a large area and a gate pad electrode having a small area. A metal film is formed on the surfaces of the gate pad electrode and the source pad electrode by a plating method or the like. The metal film is formed of, for example, a laminated film of a nickel (Ni) layer and a gold (Au) layer.

### SUMMARY

When the metal film is formed on the source pad electrode having a large are and the gate pad electrode having a small area in Patent Document 1 by the plating method at the same time, welling out of nickel from the surface of gold layer by thermal history, undeposition (deposition failure) of the gold layer on the palladium (Pd) layer, and excessive deposition of zinc (Zn) occur. This causes a wire bonding defect on the gate pad electrode having a small area.

Other objects and novel features will become apparent from the description of this specification and the accompanying drawings.

According to a semiconductor device of one embodiment, a dielectric layer has a first opening exposing a surface of a first conductive layer and a second opening exposing a surface of a second conductive layer and having an opening area smaller than an opening area of the first opening. A material of the surface of the second conductive layer exposed from the second opening is different from a material of the surface of the first conductive layer exposed from the first opening, and includes aluminum.

A manufacturing method of a semiconductor device according to one embodiment includes the following steps.

A first layer made of a material including aluminum is formed. A cover dielectric layer exposing a first pad region of the first layer is formed. A dielectric layer having a first opening exposing the first pad region of the first layer and a second opening having an opening area smaller than an opening area of the first opening and exposing a surface of the cover dielectric layer, is formed. A plating layer is formed on the first pad region of the first layer exposed from the first opening by an electroless plating method. The cover dielectric layer exposed from the second opening is removed to expose a second pad region of the first layer from the second opening.

According to the above-described embodiment, it is possible to realize a semiconductor device and method of manufacturing the same in which a wire bonding defect is less likely to occur.

### BRIEF DESCRIPTION OF THE DRAWINGS

FIG. 1 is a cross-sectional view showing a configuration of a semiconductor device according to one embodiment.

FIG. 2 is a plan view showing the configuration of the semiconductor device according to one embodiment, in which a sealing resin is omitted.

FIG. 3 is a cross-sectional view along III-III line of FIG. 2.

FIG. 4 is an enlarged cross-sectional view of a portion of FIG. 3.

FIG. 5 is a cross-sectional view showing a first step in a manufacturing method of a semiconductor device according to one embodiment.

FIG. 6 is a cross-sectional view showing a second step in the manufacturing method of the semiconductor device according to one embodiment.

FIG. 7 is a cross-sectional view showing a third step in the manufacturing method of the semiconductor device according to one embodiment.

FIG. 8 is a cross-sectional view showing a fourth step in the manufacturing method of the semiconductor device according to one embodiment.

FIG. 9 is a cross-sectional view showing a fifth step in the manufacturing method of the semiconductor device according to one embodiment.

FIG. 10 is a cross-sectional view showing a sixth step in the manufacturing method of the semiconductor device according to one embodiment.

FIG. 11 is a diagram showing a configuration in which an etching tank is added to a plating apparatus.

FIG. 12 is a cross-sectional view showing a state in which welling out of nickel occurs in a semiconductor device according to a comparative example.

FIG. 13 is a cross-sectional view showing a state in which undeposition of the gold layer occurs in the semiconductor device according to the comparative example.

FIG. 14 is a cross-sectional view showing a state in which excessive deposition of zinc occurs in the semiconductor device according to the comparative example.

FIG. 15 is a cross-sectional view showing a configuration in which a power MOSFET is formed in a semiconductor substrate.

### DETAILED DESCRIPTION

Hereinafter, embodiments of the present disclosure will be described in detail with reference to the drawings. In the specification and drawings, the same or corresponding components are denoted by the same reference numerals, and a repetitive description thereof is not repeated. In the drawings, for convenience of explanation, the configuration or manufacturing method may be omitted or simplified.

Note that a plan view in this specification means a viewpoint viewed from a direction perpendicular to a first surface FS of the semiconductor substrate. A planar shape also means a shape in plan view. Also, an opening area means an area of the opening in plan view.

### Configuration of Semiconductor Device

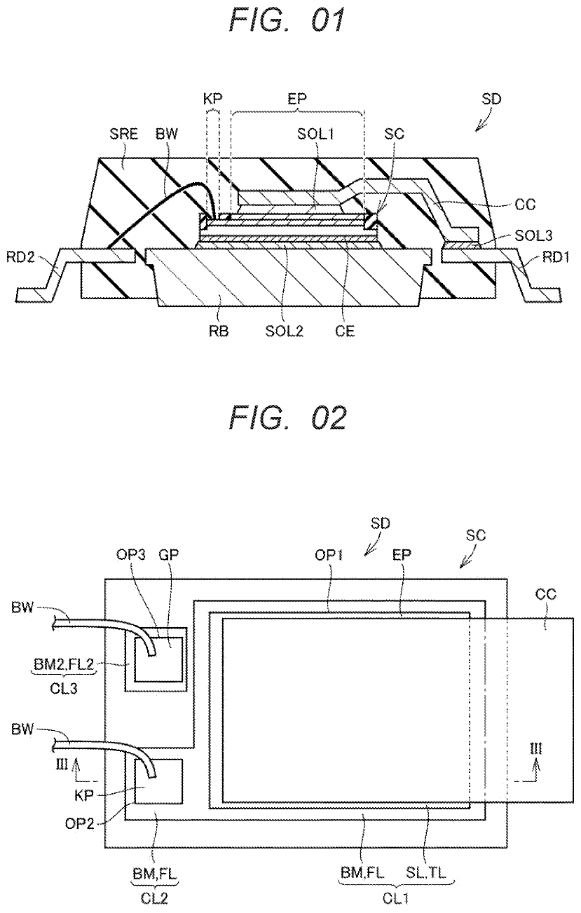

First, a configuration of a semiconductor device according to one embodiment of the present disclosure will be described with reference to FIGS. 1 to 4.

As shown in FIG. 1, the semiconductor device SD according to the present embodiment is, for example, a semiconductor package in which a semiconductor chip SC is sealed with a sealing resin SRE. The semiconductor device SD of the present embodiment includes a chip mounting portion RB, a semiconductor chip SC, lead portions RD1, RD2, a clip conductor CC, a bonding wire BW, and a sealing resin SRE.

The semiconductor chip SC is mounted on the chip mounting portion RB via a solder SOL2. Each of the lead portions RD1, RD2 is arranged spaced apart from the chip mounting portion RB. The clip conductor CC electrically connects an emitter pad EP of the semiconductor chip SC and the lead portion RD1. The clip conductor CC is connected to the emitter pad EP of the semiconductor chip SC via a solder SOL1. The clip conductor CC is connected to the lead portion RD1 via a solder SOL3. The bonding wire BW electrically connects a Kelvin emitter pad KP of the semiconductor chip SC and the lead portion RD2.

The sealing resin SRE seals the chip mounting portion RB, the semiconductor chip SC, the lead portions RD1, RD2, the clip conductor CC, and the bonding wire BW. A part of each of the chip mounting portion RB and the lead portions RD1, RD2 is exposed from the sealing resin SRE. The sealing resin SRE is made of, for example, a thermosetting resin material, and may include, for example, a filler (for example, a filler made of silica particles).

As shown in FIG. 2, the semiconductor device SD according to the present embodiment includes an emitter pad EP, a Kelvin emitter pad KP, and a gate pad GP. Each of the emitter pad EP, the Kelvin emitter pad KP, and the gate pad GP has a rectangular planar shape. The plane occupied area of the emitter pad EP is larger than the plane occupied area of each of the Kelvin emitter pad KP and the gate pad GP.

The emitter pad EP is electrically connected, for example, to the clip conductor CC. The clip conductor CC is a plate conductor. The clip conductor CC is made of metal having a low electrical resistivity such as copper (Cu), silver (Ag), for example.

By using the clip conductor CC, it is possible to flow more current than when connecting a bonding wire to the emitter pad EP. On the other hand, a bonding wire BW is individually connected to each of the Kelvin emitter pad KP and the gate pad GP. Although the case where the bonding wire BW is connected to both the Kelvin emitter pad KP and the gate pad GP is described, the clip conductor may be connected to either one of the Kelvin emitter pad KP and the gate pad GP.

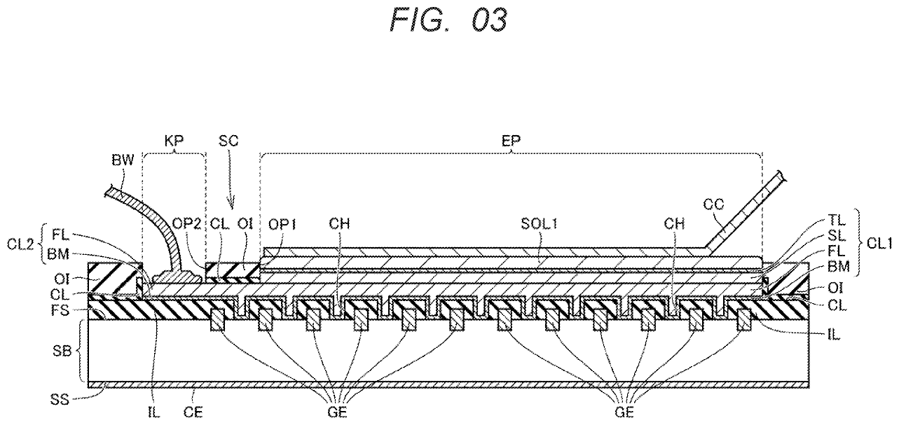

As shown in FIG. 3, the semiconductor chip SC has a semiconductor substrate SB. The semiconductor substrate SB has a first surface FS and a second surface SS facing each other. In the semiconductor substrate SB, an electric element having a vertical-type insulated gate field effect transistor portion is formed. The electric element is, for example, an IGBT. The vertical-type electric element means an electric element in which a current flows between the first surface FS and the second surface SS of the semiconductor substrate SB. The electric element may be a power MOSFET as described below.

An interlayer dielectric layer IL is arranged on the first surface FS of the semiconductor substrate SB. A contact hole CH is provided in the interlayer dielectric layer IL. The contact hole CH reaches the first surface FS of the semiconductor substrate SB from an upper surface of the interlayer dielectric layer IL.

The semiconductor device SD further includes a conductive layer CL1, a conductive layer CL2, and a conductive layer CL3 (FIG. 2). Each of the conductive layers CL1, CL2, CL3 is arranged on the first surface FS of the semiconductor substrate SB and on the interlayer dielectric layer IL.

The conductive layer CL1 (first conductive layer) is directly connected to an emitter region (impurity region) of IGBT via the contact hole CH in the interlayer dielectric layer IL. The conductive layer CL1 has the emitter pad EP. In a region directly below the conductive layer CL1, a gate electrode GE of the IGBT is arranged.

The conductive layer CL2 (second conductive layer) is connected to the conductive layer CL1. The conductive layer CL2 has the Kelvin emitter pad KP. In a region directly below the conductive layer CL2, the gate electrode GE of the IGBT is not arranged. The gate electrode GE may be arranged directly below the conductive layer CL2, and the arrangement of the gate electrode is not limited.

As shown in FIGS. 2 and 3, the conductive layer CL3 (second conductive layer) is arranged separately from each of the conductive layer CL1 and the conductive layer CL2. The conductive layer CL3 is electrically connected to the gate electrode GE of the IGBT via a contact hole (not shown) in the interlayer dielectric layer IL. The conductive layer CL3 has the gate pad GP.

As shown in FIG. 3, the conductive layer CL1 includes a barrier metal layer BM, a first layer FL, a second layer SL, and a third layer TL. The barrier metal layer BM is arranged in contact with the upper surface of the interlayer dielectric layer IL and a wall surface of the contact hole CH. The barrier metal layer BM is made of, for example, titanium-tungsten (TiW). The barrier metal layer BM may be a single layer of titanium (Ti) or titanium nitride (TiN), also may be a laminated film of titanium and titanium nitride.

The first layer FL is arranged in contact with an upper surface of the barrier metal layer BM and fills the contact hole CH. The first layer FL is made of, for example, a material including aluminum (Al), and is made of, for example, pure aluminum, an alloy of aluminum and silicon (Si), an alloy of aluminum and copper, or an alloy of aluminum and silicon and copper.

The second layer SL is arranged on the first layer FL. The second layer SL is made of a material including a first metal. The first metal is different from aluminum, and is for example, nickel. The first metal may include a small amount of phosphorus (P) in nickel.

Zinc may exist between the first layer FL and the second layer SL. Zinc is the rest of the zinc coating formed when the first layer FL is subjected to a zincate treatment.

The third layer TL is arranged on the second layer SL. Specifically, the third layer TL is arranged in contact with an upper surface of the second layer SL. The third layer TL is made of a material including a second metal. The second metal is different from the first metal, and is for example, gold.

The conductive layer CL2 includes the barrier metal layer BM and the first layer FL. The barrier metal layer BM of the conductive layer CL2 is connected to the barrier metal layer BM of the conductive layer CL1, and is formed of the same layer. The barrier metal layer BM of the conductive layer CL2 is arranged in contact with the upper surface of the interlayer dielectric layer IL.

The first layer FL of the conductive layer CL2 is connected to the first layer FL of the conductive layer CL1 and is formed of the same layer. The first layer FL of the conductive layer CL2 is arranged in contact with an upper surface of the barrier metal layer BM of the conductive layer CL2.

As shown in FIG. 2, the conductive layer CL3 includes a barrier metal layer BM2 and a first layer FL2. The barrier metal layer BM2 is formed by being separated from the same layer as the barrier metal layer BM of the conductive layer CL1 and the conductive layer CL2 by patterning. The barrier metal layer BM2 is arranged in contact with the upper surface of the interlayer dielectric layer IL and the inner wall surface of the contact hole. Thus the barrier metal layer BM2 is directly connected to the gate electrode GE.

The first layer FL2 is formed by being separated from the same layer as the first layer FL of the conductive layers CL1, CL2 by patterning. The first layer FL2 is arranged in contact with an upper surface of the barrier metal layer BM2.

Since the configuration of the conductive layer CL3 other than the above is substantially the same as the configuration of the conductive layer CL2, the explanation thereof will not be repeated.

As shown in FIGS. 2 and 3, a cover dielectric layer CL and a dielectric layer OI (organic dielectric layer) are arranged so as to cover each of the conductive layers CL1, CL2, CL3. The dielectric layer OI is made of a material including an organic insulator. The organic insulator included in the dielectric layer OI is, for example, polyimide.

The cover dielectric layer CL is arranged between the dielectric layer OI and the semiconductor substrate SB and between the dielectric layer OI and the first layer FL. The cover dielectric layer CL is made of, for example, a silicon nitride film (Si₃N₄), a silicon oxynitride film (SiON), a silicon oxide film (SiO₂), or the like.

Openings OP1, OP2, OP3 are provided in the cover dielectric layer CL and the dielectric layer OI with. Each of the openings OP1, OP2, OP3 penetrates through both the cover dielectric layer CL and the dielectric layer OI and reaches surfaces of the first layers FL, FL2.

The second layer SL and the third layer TL are arranged in the opening OP1 (first opening). The opening OP1 exposes a surface of the conductive layer CL1. The surface of the conductive layer CL1 exposed from the opening OP1 is an upper surface of the third layer TL. Therefore, the material of the surface of the conductive layer CL1 exposed from the opening OP1 is, for example, gold. The upper surface of the third layer TL1 is exposed from the dielectric layer OI to form the emitter pad EP.

The opening OP2 (second opening) exposes a surface of the conductive layer CL2. The opening OP2 has an opening area smaller than an opening are of the opening OP1. The surface of the conductive layer CL2 exposed from the opening OP2 is an upper surface of the first layer FL. Therefore, the material of the surface of the conductive layer CL2 exposed from the opening OP2 is a material including aluminum, and is a material different from the material of the surface of the conductive layer CL1 exposed from the opening OP1. The upper surface of the first layer FL of the conductive layer CL2 is exposed from the dielectric layer OI to form the Kelvin emitter pad KP.

As shown in FIG. 2, the opening OP3 (second opening) exposes a surface of the conductive layer CL3. The opening OP3 has an opening area smaller than the opening area of the opening OP1. The surface of the conductive layer CL3 exposed from the opening OP3 is an upper surface of the first layer FL2. Therefore, the material of the surface of the conductive layer CL3 exposed from the opening OP3 is a material including aluminum, and is a material different from the material of the surface of the conductive layer CL1 exposed from the opening OP1. The upper surface of the first layer FL2 of the conductive layer CL3 is exposed from the dielectric layer OI to form the gate pad GP.

As shown in FIG. 3, a solder SOL1 is arranged on the surface of the conductive layer CL1 exposed from the opening OP1. The solder SOL1 is in contact with the upper surface of the conductive layer CL1. That is, the solder SOL1 is in contact with the upper surface of the third layer TL1 configuring the emitter pad EP.

The clip conductor CC is arranged on the emitter pad EP. The clip conductor CC is electrically connected to the emitter pad EP via the solder SOL1. That is, the clip conductor CC is connected to the upper surface of the third layer TL of the conductive layer CL1 via the solder SOL1. Other than the solder SOL1, a bonding method using a silver sintering or silver paste may be used to connect the clip conductor CC and the emitter pad EP.

The bonding wire BW is directly connected to the surface of the conductive layer CL2 exposed from the opening OP2. That is, the bonding wire BW is directly connected to the upper surface of the first layer FL configuring the Kelvin emitter pad KP.

As shown in FIG. 2, a bonding wire BW is directly connected to the surface of the conductive layer CL3 exposed from the opening OP3. That is, the bonding wire BW is directly connected to the upper surface of the first layer FL2 configuring the gate pad GP.

As shown in FIG. 3, a collector electrode CE is arranged on the second surface SS of the semiconductor substrate SB. The collector electrode CE is electrically connected to the collector region of the IGBT.

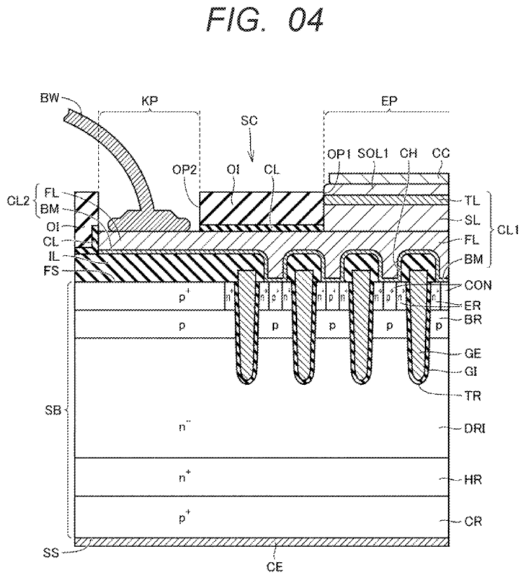

As shown in FIG. 4, the electric element formed in the semiconductor substrate SB is, for example, IGBT. The IGBT mainly includes a p⁺ collector region CR, an n⁺ region HR, an n⁻ drift region DRI, a p-type base region BR, a p⁺ contact region ER, an n⁺ emitter region GE, and a gate electrode GE.

The p⁺ collector region CR is arranged in the second surface SS of the semiconductor substrate SB. The n⁺ region HR is arranged on the p⁺ collector region CR (i.e., on a side of the first surface FS with respect to the p⁺ collector region CR). The n⁺ region HR forms a pn junction with the p⁺ collector region CR.

The n⁻ drift region DRI is arranged on the n+region HR (on a side of the first surface FS with respect to the n⁺ region HR). The n⁻ drift region DRI is in contact with the n⁺ region HR. The n⁻ drift region DRI has an n-type impurity concentration lower than an n-type impurity concentration of the n⁺ region HR.

The p-type base region BR is arranged on the n⁻ drift region DRI (on a side of the first surface FS with respect to the drift region DRI). The p-type base region BR forms a pn junction with the n⁻ drift region DRI.

The p⁺ contact region CON and the n⁺ emitter region ER (first region) are arranged on the p-type base region BR (i.e., on a side of the first surface FS with respect to the p-type base region BR). The p⁺ contact region CON is in contact with the p-type base region BR. The p⁺ contact region CON has a p-type impurity concentration higher than a p-type impurity concentration of the p-type base region BR. The n⁺ emitter region ER forms a pn junction with each of the p⁺ contact region CON and the p-type base region BR.

A trench TR is provided in the semiconductor substrate SB. The trench TR penetrates through each of the n⁺ emitter region ER and the p-type base region BR from the first surface FS and reaches the n⁻ drift region DRI. A gate dielectric layer GI is arranged along the inner wall of the trench TR. The inside of the trench TR is filled with the gate electrode GE. The gate electrode GE faces the p-type base region BR via the gate dielectric layer GI. Thus, the IGBT has an insulated gate field effect transistor portion.

The conductive layer CL1 is electrically connected to the n⁺ emitter region ER via the contact hole CH in the interlayer dielectric layer IL to form an emitter electrode. The conductive layer CL1 is also electrically connected to the p⁺ contact region CON via the contact hole CH.

The collector electrode CE is arranged on the second surface SS of the semiconductor substrate SB. The collector electrode CE is electrically connected to the p⁺ collector region CR by being in contact with the p⁺ collector region CR.

The semiconductor device SD may include a Kelvin collector pad (not shown) for detecting the potential of the collector. The Kelvin collector pad is electrically connected to the p⁺ collector region CR shown in FIG. 4. The Kelvin collector pad is arranged on the same side (that is, on the side of the first surface FS) as the emitter pad EP, the Kelvin emitter pad KP, and the like with respect to the semiconductor substrate SB. The Kelvin collector pad has an opening area smaller than an opening area of the emitter pad EP. The conductive layer configuring the Kelvin collector pad has the same configuration as the conductive layer CL2 shown in FIG. 3. Specifically, the conductive layer configuring the Kelvin collector pad is configured by being separated from the same layer as the barrier metal layer BM and the first layer FL of the conductive layer CL2 shown in FIG. 3. The bonding wire is connected to the Kelvin collector pad. The bonding wire is directly connected to the first layer made of a material including aluminum in the Kelvin collector pad. Note that the other configuration of the Kelvin collector pad is substantially the same as the Kelvin emitter pad, and therefore, the description thereof will not be repeated.

### Manufacturing Method of Semiconductor Substrate

Next, the manufacturing method of semiconductor device of the present embodiment will be described with reference to FIGS. 5 to 10 and FIG. 3.

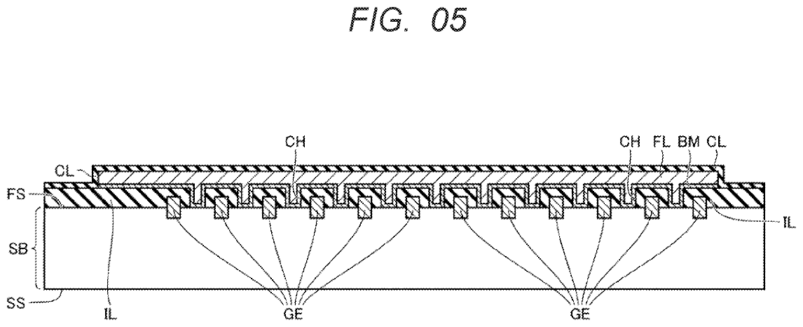

As shown in FIG. 5, first, the semiconductor substrate SB is prepared. The electric element (not shown) having the gate electrode GE such as IGBT is formed in the semiconductor substrate SB. The gate electrode GE is formed of, for example, polycrystalline silicon in which impurities are introduced.

To cover the first surface FS of the semiconductor substrate SB, for example, the interlayer dielectric layer IL formed of a silicon oxide film is formed. In the interlayer dielectric layer IL, the contact hole CH is formed by a photolithography technique and an etching technique. The contact hole CH reaches each of the n⁺ emitter region ER and the p⁺ contact region CON from the upper surface of the interlayer dielectric layer IL.

On the interlayer dielectric layer IL, the barrier metal layer made of, for example, titanium-tungsten and the first layer made of, for example, a material including aluminum are formed by laminating in order. The barrier metal layer is formed so as to be in direct contact with each of the n⁺ emitter region ER and the p⁺ contact region CON via the contact hole CH. The first layer is formed to be in contact with the upper surface of the barrier metal layer. The first layer is made of, for example, pure aluminum, an alloy of aluminum and silicon (Si), an alloy of aluminum and copper, or an alloy of aluminum and silicon and copper.

The first layer and the barrier metal layer are patterned by the photolithography technique and the etching technique. Thus, the barrier metal layer is separated into the barrier metal layers BM, BM2 (FIG. 2). Also, the first layer is separated into the first layers FL, FL2 (FIG. 2). In addition, a laminated structure of the barrier metal layer BM and the first layer FL and a laminated structure of the barrier metal layer BM2 and the first layer FL2 are formed.

Thereafter, the cover dielectric layer CL is formed on the entire surface of the first surface FS of the semiconductor substrate SB. The cover dielectric layer CL is formed so as to cover the laminated structure of the barrier metal layer BM and the first layer FL and the laminated structure of the barrier metal layer BM2 and the first layer FL2. The cover dielectric layer CL is formed of, for example, a silicon nitride film, a silicon oxynitride film, a silicon oxide film, or the like.

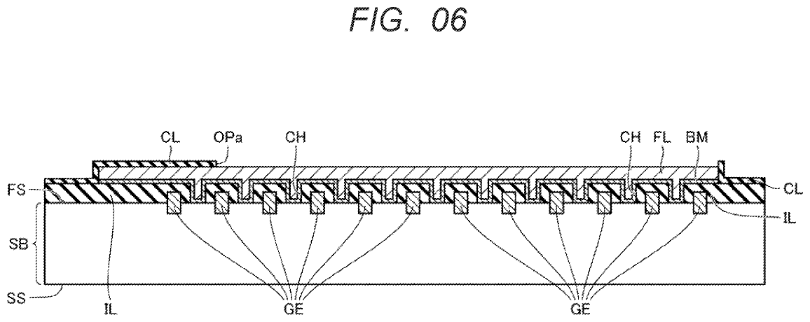

As shown in FIG. 6, the cover dielectric layer CL is patterned by the photolithography technique and the etching technique. As a result, an opening OPa is formed in the cover dielectric layer CL. A part of the surface of the first layer FL (emitter pad region (first pad region)) is exposed from the opening OPa. Accordingly, the cover dielectric layer CL exposing the emitter pad region of the first layer FL is formed.

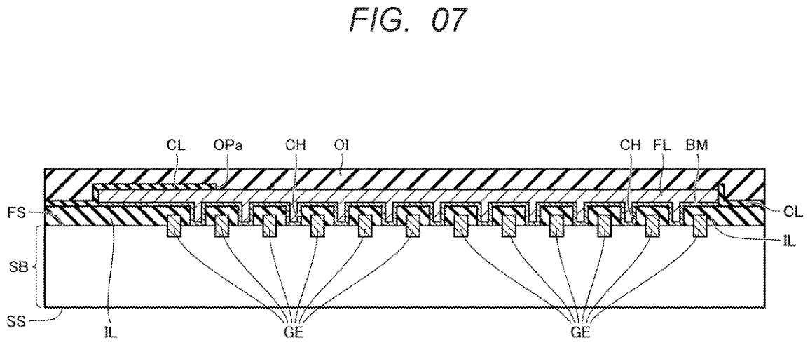

As shown in FIG. 7, the dielectric layer OI is then applied to the entire surface of the first surface FS of the semiconductor substrate SB. The dielectric layer OI is formed so as to cover the laminated structure of the barrier metal layer BM and the first layer FL and the laminated structure of the barrier metal layer BM2 and the first layer FL2. The dielectric layer OI is formed so as to cover the surface of the first layer FL exposed from the opening OPa. The dielectric layer OI is, for example, an photosensitive film, and is polyimide.

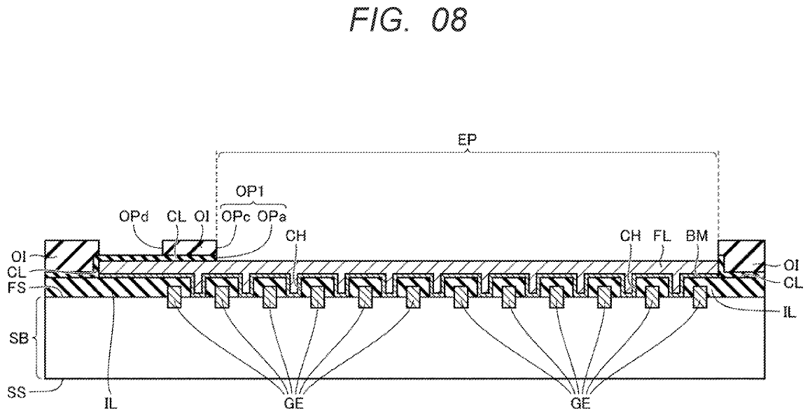

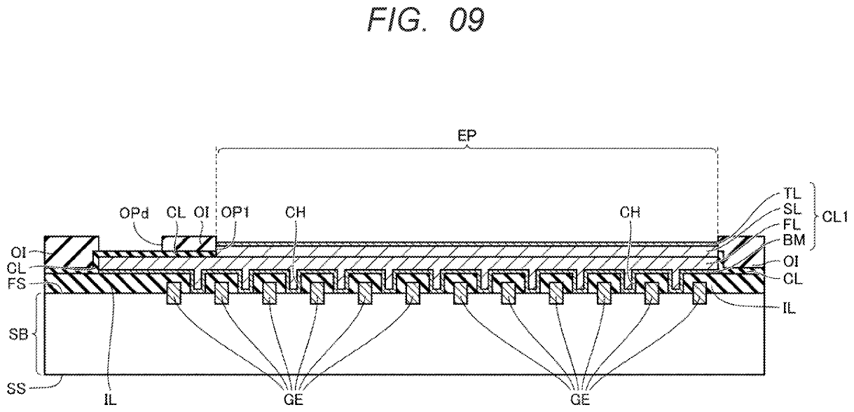

As shown in FIG. 8, the dielectric layer OI is patterned by the photolithography technique (exposure and development). As a result, openings OPc, OPd are formed in the dielectric layer OI. The opening OPc is formed so as to communicate with the opening OPa in the cover dielectric layer CL. The opening OPa and the opening OPc form the opening OP1 defining the emitter pad EP. A part of the surface of the first layer FL is exposed from the opening OP1.

The opening OPd is formed so as to expose the surface of the cover dielectric layer CL. As a result, the dielectric layer OI having the opening OP1 exposing the emitter pad region of the first layer FL and the opening OPd having an opening area smaller than an opening area of the opening OP1 and exposing the surface of the cover dielectric layer CL, is formed.

As shown in FIG. 9, a plating layer is formed on the emitter pad region of the first layer FL exposed from the opening OP1 by using an electroless plating method. The forming the plating layer includes forming the second layer SL made of a material including nickel on the first layer FL, and forming the third layer TL made of a material including gold on the second layer SL. The forming the second layer SL and the third layer TL by plating will be specifically described below.

First, the first layer FL is cleaned by a degreasing treatment. Thereafter, the oxide layer on the surface is removed by an etching treatment, and then, after the acid cleaning is performed, the first zincate treatment is performed. Next, zinc (Zn) formed in the first zincate treatment is removed by the acid cleaning. Next, a second zincate treatment is performed on the first layer FL. In the second zincate treatment, the zincate liquid is brought into contact with the surface, and a zinc coating film is formed on the surface by a substitution reaction between aluminum and zinc. The zincate treatment is performed to facilitate plating on the aluminum surface. For example, nickel plating and gold plating are performed as electroless plating on the first layer FL on which the zinc coating film is formed. A pure water cleaning treatment is performed between each process. When hypophosphorous acid is used as the reducing agent in the electroless nickel plating solution, a small amount of phosphorus (P) is included in the nickel film.

By the nickel plating and the gold plating, the second layer SL made of nickel and the third layer TL made of gold are formed on the first layer FL1 (Ni/Au). As a result, the upper surface of the third layer TL configures the emitter pad EP. The third layer TL is formed to be in contact with the second layer SL.

It should be noted that by nickel plating, there remains little zinc coating film on each surface of the first layers FL, FL2. However, a small amount of zinc may remain on each surface of the first layers FL, FL2. Further, the third layer TL may be made of palladium by performing palladium plating on nickel plating (Ni/Pd). Palladium plating may be performed between nickel plating and gold plating (Ni/Pd/Au). The plating performed between the nickel plating and the gold plating is not limited to the palladium plating, but may be plating of a noble metal with respect to solder, bonding wires, and the like.

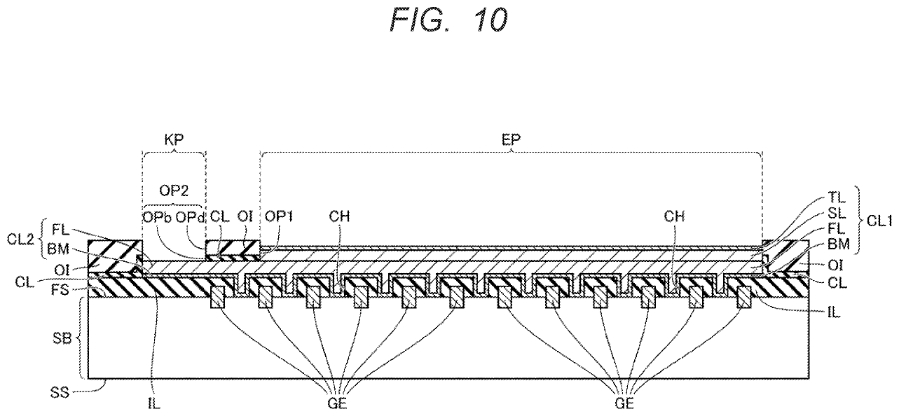

As shown in FIG. 10, the cover dielectric layer CL exposed from the opening OPd in the dielectric layer OI is removed by wet etching using, for example, hydrofluoric acid. By the wet etching, the cover dielectric layer CL exposed from the opening OPd is removed, and the surface of the Kelvin emitter pad region (second pad region) of the first layer FL is exposed.

Instead of wet etching, the cover dielectric layer CL exposed from the opening OPd may be removed by dry etching using a resist mask, and the surface of the Kelvin emitter pad region of the first layer FL may be exposed.

By removing the cover dielectric layer CL exposed from the opening OPd, the opening OPb communicating with the opening OPd is formed in the cover dielectric layer CL. The opening OPb and the opening OPd form the opening OP2 defining the Kelvin emitter pad KP. The Kelvin emitter pad region of the first layer FL is exposed from the opening OP2.

Note that the opening OP3 defining the gate pad GP and the conductive layer CL1 shown in FIG. 2 are formed in the same manner as the opening OP2 defining the Kelvin emitter pad KP and the conductive layer CL2 described above.

As shown in FIG. 3, after the second surface SS of semiconductor substrate SB is polished to a predetermined thickness, a collector electrode CE is formed on the second surface SS. As the collector electrode CE, an alloyed layer of aluminum and silicon (Si), a titanium layer, a nickel layer, and a gold layer are laminated from a side of the semiconductor substrate SB. Thereafter, the semiconductor wafer is diced and divided into semiconductor chips SC.

In a state of the semiconductor chip SC, the clip conductor CC is connected to the plating layer (third layer TL) exposed in the emitter pad region via the solder SOL1. That is, the clip conductor CC is connected to the emitter pad EP via the solder SOL1.

Also, in the state of semiconductor chip, the bonding wire BW is directly connected to the first layers FL, FL2 exposed in each of the Kelvin emitter pad region and the gate pad region. That is, the bonding wire BW is directly connected to each of the Kelvin emitter pad KP and the gate pad GP.

As described above, the semiconductor device SD of the present embodiment is manufactured.

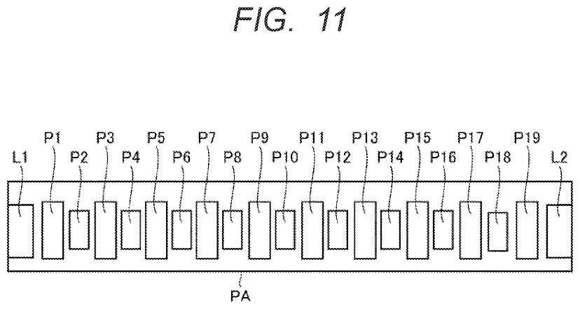

It should be noted that the wet etching performed in FIG. 10 is performed by a conventional wet etching apparatus as a separate step from the plating performed in FIG. 9. The wet etching performed in FIG. 10 may also be performed continuously after the end of the plating performed in FIG. 9. In this instance, the plating apparatus performing the plating performed in FIG. 9 additionally includes an etching tank for the wet etching performed in FIG. 10. Hereinafter, a plating apparatus including the etching tank will be described with reference to FIG. 11.

As shown in FIG. 11, the plating apparatus PA includes, in order from a load portion L1 toward an unload portion L2, a cleaner tank P1, an etching tank P3, an acid treatment tank P5, a zincate tank P7, an electroless nickel tank P9, an electroless palladium tank P11, an electroless gold tanks P13, P15, a dielectric film etching tank P17, and a drying portion P19. The plating apparatus PA further includes water washing tanks P2, P4, P6, P8, P10, P12, P14, P16, P18.

As described above, the plating apparatus PA has the dielectric film etching tank P17. The dielectric film etching tank P17 is located closer to the unload portion L2 than the electroless gold tank P15 and the water washing tank P16. In this way, wet etching can be continuously performed after the plating is completed in the plating apparatus PA.

### Effects

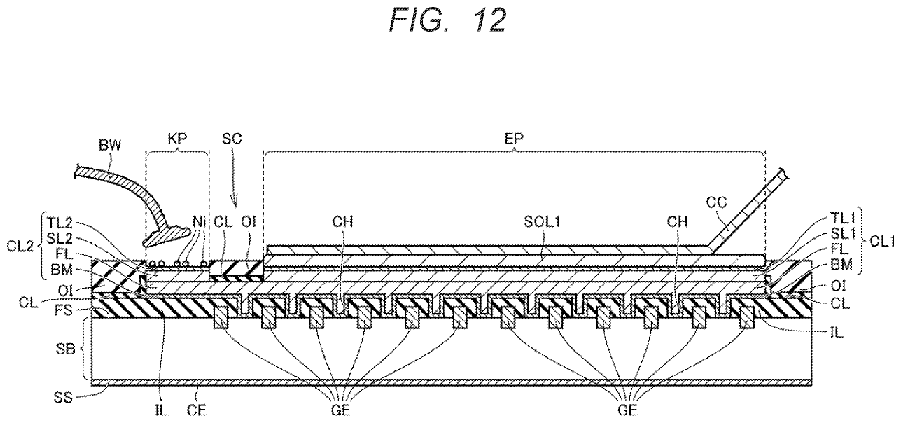

Next, the effects in the present embodiment will be described in comparison with the comparative example shown in FIGS. 12 to 14.

As shown in FIGS. 12 to 14, in the comparative example, a metal film is formed by a plating method on both the emitter pad EP having a large area and the Kelvin emitter pad KP having a small area.

Specifically, as shown in FIG. 12, the conductive layer CL1 includes a barrier metal layer BM and a first layer FL, and further includes a second layer SL1 and a third layer TL1 formed by plating on the first layer FL. Similarly to the conductive layer CL1, the conductive layer CL2 also includes a barrier metal layer BM and a first layer FL, and further includes a second layer SL2 and a third layer TL2 formed by plating on the first layer FL.

Each of the second layers SL1, SL2 is made of, for example, a material including nickel, and each of the third layers TL1, TL2 is made of, for example, a material including gold.

In this comparative example, as shown in FIG. 12, in both the emitter pad EP having a large area and the Kelvin emitter pad KP having a small area, nickel is welled out on the surface of the third layers TL1, TL2 due to the thermal history. The welling out of nickel occurs when nickel in the second layers SL1, SL2 reaches the upper surface of the third layers TL1, TL2 through the gold grain boundaries in the third layers TL1, TL2.

When a emitter pad EP having a large area is connected by solder, the influence of welling out of nickel is small due to the superiority of a combination of a large area and a solder connection. On the other hand, when the Kelvin emitter pad KP having a small area is connected by a bonding wire, there is a large influence of the welling out of nickel.

For this reason, peeling of the bonding wire BW is likely to occur when nickel is welled out at the connecting portion of the Kelvin emitter pad KP having a small area to which the bonding wire BW is connected.

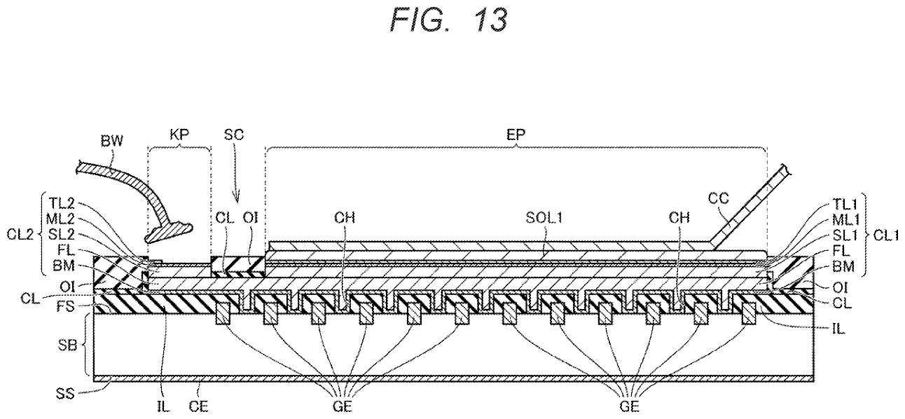

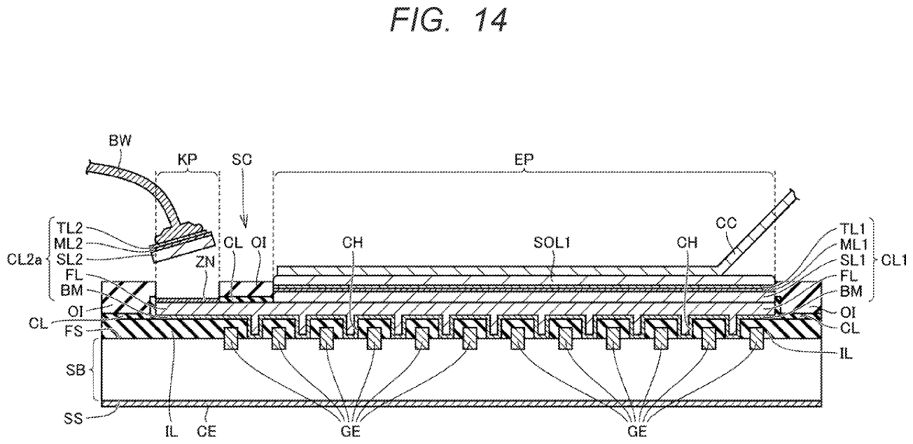

As shown in FIGS. 13 and 14, it is conceivable to arrange intermediate layers ML1, ML2 between the second layers SL1, SL2 and the third layers TL1, TL2 in order to suppress the welling out of nickel. The intermediate layers ML1, ML2 are made of, for example, a material including palladium. A layer including a noble metal such as palladium functions as a nickel barrier film. Therefore, the arrangement of the intermediate layers ML1, ML2 can prevent the welling out of nickel.

However, even when the intermediate layers ML1, ML2 are arranged, the problem of generation of undeposition portion of the third layer TL2 occurs in the Kelvin emitter pad KP having a small area as shown in FIG. 13. Hereinafter, the problem will be described.

As shown in FIG. 13, electrons (Ni→Ni⁺+e⁻) generated in the Kelvin emitter pad KP having a small area may flow to the emitter region ER (FIG. 4). In this case, gold is not sufficiently deposited on the Kelvin emitter pad KP having a small area, and a portion where the third layer TL2 is not formed is generated. As described above, in the Kelvin emitter pad KP having a small area, the area difference between the emitter pad EP and the Kelvin emitter pad KP causes a portion where the third layer TL2 is not sufficiently formed. Therefore, the bonding wire BW is not easily connected to the Kelvin emitter pad KP, and the bonding wire BW is easily peeled off.

In particular, in a configuration in which the intermediate layer SL2 is arranged between the second layer TL2 and the third layer SL2, the electrons emitted from the second layer ML2 are received by Au ions through the intermediate layer ML2. As a result, undeposition of the third layer TL2 will be remarkable as compared with the laminated structure of the nickel layer and the gold layer in which electrons are received by Au ions at the surface of the second layer SL2.

In addition, even when the intermediate layers ML1, ML2 are arranged, the problem of excessive deposition of zinc on the first layer FL occurs in the Kelvin emitter pad KP having a small area as shown in FIG. 14. Hereinafter, the problem will be described.

As shown in FIG. 14, the emitter pad EP and the Kelvin emitter pad KP share the first layer FL made of aluminum. The first layer FL is exposed in a large area from the dielectric layer OI in a region serving as the emitter pad EP, and is exposed in a small area from the dielectric layer OI in a region serving as the Kelvin emitter pad.

When the zincate treatment is performed on the first layer FL made of aluminum, the reaction “Al→Al³⁺+3e⁻” occurs on Al of the first layer FL. In addition, Zn²⁺ in the chemical solution obtains electrons (e⁻) in the first layer FL, and the reaction “Zn²⁺+2e⁻→Zn” occurs. As a result, a zinc coating film is formed on the first layer FL. The reaction stops when the entire surface of the aluminum surface is replaced with zinc. In addition, in the zincate treatment, Zn²⁺ in the chemical solution is not sufficiently supplied to the first layer FL of the emitter pad EP region exposed with a large area, but is sufficiently supplied to the first layer FL of the Kelvin emitter pad KP region exposed with a small area. Therefore, the electrons (e⁻) remaining in the first layer FL move in the first layer FL from a side of the emitter pad EP region exposed with a large area to a side of the Kelvin emitter pad KP region exposed with a small area.

As a result, zinc is excessively deposited on the first layer FL in the Kelvin emitter pad KP region exposed with a small area, and a zinc film ZN having a large film thickness is grown. In the Kelvin emitter pad KP region, the adhesion between the first layer FL and the second layer SL2 is reduced by the thick zinc coating film ZN, peeling off of the portion where the bonding wire BW is connected is likely to occur.

In contrast, in the present embodiment, as shown in FIGS. 2 and 3, the bonding wire BW is directly connected to the first layer FL made of a material including aluminum in the small area pads such as the Kelvin emitter pad KP and the gate pad GP. As described above, there is no nickel layer, gold layer, or other plating layer at the location where the bonding wire BW is connected, so that welling out of nickel (FIG. 12), undeposition of the third layer TL2 (FIG. 13), and excessive deposition of zinc (FIG. 14) is not occurred. Further, the bonding property between the bonding wire BW and the material including aluminum is good. Therefore, the bonding wire BW is hardly peeled off from the small area pad.

Further, according to the present embodiment, as shown in FIG. 3, in the emitter pad EP having a large area, the plate clip conductor CC is connected via the solder SOL1. Therefore, in the present embodiment, a larger amount of current can be caused to flow than the linear bonding wire.

According to the present embodiment, as shown in FIG. 3, the conductive layer CL1 includes the first layer FL made of a material including aluminum, the second layer SL made of a material including nickel, and the third layer TL made of a material including gold. This facilitates connecting the clip conductor CC to the conductive layer CL1 via the solder SOL1.

According to the present embodiment, as shown in FIG. 3, the third layer TL is in contact with the second layer SL. As described above, since an extra layer is not required between the second layer SL and the third layer TL, the conductive layer CL1 can be formed with a simple configuration.

Also, the solder SOL1 is wettable to nickel. Therefore, even if a layer such as palladium is not arranged between the second layer SL and the third layer TL, the clip conductor CC can be connected to the conductive layer CL1 with good bondability via the solder SOL1.

According to the present embodiment, as shown in FIG. 3, the conductive layer CL1 is connected to the emitter region ER. This allows a large current to flow through the clip conductor CC.

According to the present embodiment, as shown in FIG. 3, the conductive layer CL2 is connected to either the emitter region or the gate electrode GE. As a result, the potential of the emitter can be detected through the Kelvin emitter pad KP, and the potential of the gate electrode GE can be controlled.

Further, according to the present embodiment, as shown in FIG. 9, after the plating layer (the second layer SL, the third layer TL) is formed on the first layer FL exposed from the opening OP1 by the electroless plating method, the cover dielectric layer CL exposed from the opening OPd is removed as shown in FIG. 10. Accordingly, the cover dielectric layer CL exposed from the opening OPd can be selectively removed without separately forming a dedicated mask. Therefore, the semiconductor device of the present embodiment can be manufactured with a small number of steps.

### Others

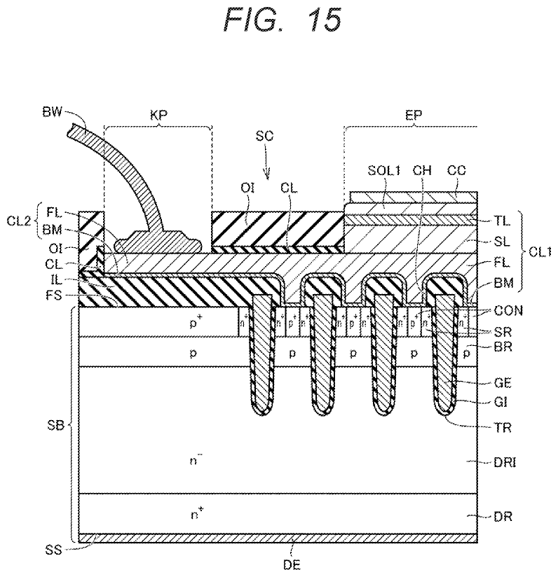

In the above embodiment, a vertical-type IGBT has been described as an electric device formed in the semiconductor substrate SB. However, the electric device to which the present disclosure is applied is not limited to the vertical-type IGBT, and may be a vertical-type power MOSFET as shown in FIG. 15.

As shown in FIG. 15, the vertical-type power MOSFET has an n⁺ drain region DR, an n⁻ drift region DRI, a p-type base region BR, a p⁺ contact region CON, an n⁺ source region SR, and a gate electrode GE.

The n⁺ drain region DR is arranged in the second surface SS of the semiconductor substrate SB. The n⁻ drift region DRI is arranged so as to be in contact with the n⁺ drain region DR. The n⁻ drift region DRI has an n-type impurity concentration lower than an n-type impurity concentration of the n⁺ drain region DR. The p-type base region BR is arranged on the n⁻ drift region DRI (on a side of the first surface FS with respect to the n⁻ drift region DRI) so as to form a pn junction with the n⁻ drift region DRI.

The p⁺ contact region CON and the n⁺ source region SR are arranged on the p-type base region BR (on a side of the first surface FS with respect to the p-type base region BR) so as to be in contact with the p-type base region BR. The p⁺ contact region CON has a p-type impurity concentration higher than a p-type impurity concentration of the p-type base region BR. The n⁺ source region SR forms a pn junction with each of the p⁺ contact region CON and the p-type base region BR.

A trench TR that penetrates each of the n⁺ source region SR and the p-type base region BR from the first surface FS and reaches the n⁻ drift region DRI is provided in the semiconductor substrate SB. The gate dielectric layer GI is arranged along the wall surface of trench TR. The inside of the trench TR is filled with the gate electrode GE. The gate electrode GE faces the p-type base region BR via the gate dielectric layer GI. Thus, the power MOSFET has an insulated gate field effect transistor portion.

The conductive layer CL1 is in contact with the n⁺ source region SR through the contact hole CH in the interlayer dielectric layer IL to form a source electrode. The conductive layer CL1 has the source pad SP exposed from the dielectric layer OI. In the present embodiment, the Kelvin emitter pad KP in the above-described embodiment serves as a Kelvin source pad, and the Kelvin source pad measures the potential of the n⁺ source region SR. The conductive layer arranged on the second surface SS of the semiconductor substrate SB is in contact with the n⁺ drain region DR to form a drain electrode DE.

Even in such a MOSFET, the same effects as those of the above-described embodiment can be obtained.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a first conductive layer;
a second conductive layer; and
a dielectric layer having a first opening and a second opening, the first opening exposing a surface of the first conductive layer, the second opening exposing a surface of the second conductive layer and having an opening area smaller than an opening area of the first opening,
wherein a material of the surface of the second conductive layer exposed from the second opening is different from a material of the surface of the first conductive layer exposed from the first opening, and includes aluminum.

2. The semiconductor device according to claim 1, comprising:
a solder connected to the surface of the first conductive layer exposed from the first opening;
a plate clip conductor electrically connected to the first conductive layer with the solder interposed between the first conductive layer and the plate clip conductor; and
a bonding wire directly connected to the surface of the second conductive layer exposed from the second opening.

3. The semiconductor device according to claim 1,
wherein the first conductive layer includes:
a first layer made of a material including aluminum;
a second layer made of a material including nickel and arranged on the first layer; and
a third layer made of a material including gold and arranged on the second layer.

4. The semiconductor device according to claim 3,
wherein the third layer is in contact with the second layer.

5. The semiconductor device according to claim 1, comprising:
a semiconductor substrate; and
a first region arranged in the semiconductor substrate, the first region being an emitter region or a source region,
wherein the first conductive layer is electrically connected to the first region.

6. The semiconductor device according to claim 5, comprising:
a gate electrode; and
a second region arranged in the semiconductor substrate, the second region being a collector region or a drain region,
wherein the second conductive layer is electrically connected to any one of the first region, the gate electrode and the second region.

7. The semiconductor device according to claim 1,
wherein the dielectric layer is an organic dielectric layer.

8. A method of manufacturing a semiconductor device, the method comprising:
forming a first layer made of a material including aluminum;
forming a cover dielectric layer exposing a first pad region of the first layer;
forming a dielectric layer having a first opening and a second opening, the first opening exposing the first pad region of the first layer, the second opening exposing a surface of the cover dielectric layer and having an opening area smaller than an opening area of the first opening;
forming a plating layer on the first pad region of the first layer exposed from the first opening by an electroless plating method; and
removing the cover dielectric layer exposed from the second opening, thereby exposing a second pad region of the first layer from the second opening.

9. The method according to claim 8, comprising:
connecting a clip conductor to the plating layer exposed in the first pad region with a solder interposed between the plating layer and the clip conductor; and
connecting a bonding wire to the first layer exposed in the second pad region.

10. The method according to claim 8,
wherein the forming the plating layer includes:
forming a second layer made of a material including nickel on the first layer; and
forming a third layer made of a material including gold on the second layer.

11. The method according to claim 10,
wherein the third layer is formed to be in contact with the second layer.
